(19) United States
(12) Patent Application Publication
(10) Pub. No.: US 2004/0244693 A1
(43) Pub. Date: Dec. 9, 2004

(54) Electromagnetic field supply apparatus and plasma processing device

(76) Inventors: Nobuo Ishii, Hyogo (JP); Kibatsu Shinohara, Kanagawa (JP); Yasuyoshi Yasaka, Kyoto (JP); Makoto Ando, Kanagawa (JP)

Correspondence Address: Finnegan Henderson Farabow, Garrett & Dunner, 1300 I Street NW, Washington, DC, 20005-3315, US

(21) Appl. No.: 10/491,108

(22) PCT Filed: Sep. 4, 2002
(86) PCT No.: PCT/JP02/08978

(30) Foreign Application Priority Data
Sep. 27, 2001 (JP) 2001-297801
Sep. 28, 2001 (JP) 2001-300416

(51) Int. Cl. C23C 16/00

(52) U.S. Cl. 118/723 MW

(57) ABSTRACT

A apparatus includes a waveguide (21) including a first conductive plate (23) having a plurality of slots (26) and a second conductive plate (22) arranged opposite to the former plate, a cylindrical waveguide (13) connected to an opening of the second conductive plate (22), and a bump (27) provided on the first conductive plate (23) and projecting toward the opening (25) of the second conductive plate (22). At least part of the bump (27) is made of a dielectric. The cylindrical waveguide (13) larger in characteristic impedance than in a coaxial waveguide is used to generally reduce a transmission loss. The bump (27) can reduce power reflection at the connecting portion of the cylindrical waveguide (13) and waveguide (21). A transmission loss and power reflection thus reduced can enhance an electromagnetic field supply efficiency.

### BACKGROUND OF THE INVENTION

The present invention relates to an electromagnetic field supply apparatus and, more particularly, to an electromagnetic field supply apparatus that supplies an electromagnetic field propagating in a waveguide to a target through slots.

The present invention also relates to a plasma processing apparatus and, more particularly, to a plasma processing apparatus that generates a plasma by using an electromagnetic field and processes a target object such as a semiconductor or LCD (liquid crystal display) with the plasma.

In the manufacture of a semiconductor apparatus or flat panel display, plasma processing apparatuss are used often to perform processes such as formation of an oxide film, crystal growth of a semiconductor layer, etching, and ashing. Among the plasma processing apparatuss, a microwave processing apparatus is available which supplies microwaves from a radial line slot antenna (to be abbreviated as RLSA hereinafter) into a processing vessel and ionizes and dissociates a gas in the processing vessel by the operation of the electromagnetic field, thus generating a plasma. The microwave plasma processing apparatus can perform a plasma process efficiently since it can generate a low-pressure, high-density plasma.

FIG. 20 is a view showing an arrangement of a conventional microwave plasma processing apparatus. The plasma processing apparatus shown in FIG. 20 has a processing vessel 1 which accommodates a substrate 4 as a target object and processes the substrate 4 with a plasma, and an electromagnetic field supply apparatus 210 which supplies microwaves MW into the processing vessel 1 so that a plasma P is generated in the processing vessel 1 by the operation of the electromagnetic field of the plasma.

The processing vessel 1 is a bottomed cylinder with an upper opening. A substrate table 3 is fixed to the central portion of the bottom surface of the processing vessel 1 through an insulating plate 2. The substrate 4 is arranged on the upper surface of the substrate table 3. Exhaust ports 5 for vacuum evacuation are formed in the periphery of the bottom surface of the processing vessel 1. A gas introducing nozzle 6 is arranged in the side wall of the processing vessel 1 to introduce a gas into the processing vessel 1. For example, when the plasma processing apparatus is used as an etching apparatus, a plasma gas such as Ar and an etching gas such as CF₄ are introduced into it through the gas introducing nozzle 6.

The upper opening of the processing vessel 1 is sealed with a dielectric plate 7 so the plasma P generated in the processing vessel 1 does not leak outside. An RLSA 212 of the electromagnetic field supply apparatus 210 (to be described later) is disposed on the dielectric plate 7. The RLSA 212 is isolated from the processing vessel 1 by the dielectric plate 7, and is accordingly protected from the plasma P generated in the processing vessel 1. The outer surfaces of the dielectric plate 7 and RLSA 212 are covered by a shield material 8 arranged annularly on the side wall of the processing vessel 1. Thus, the microwaves MW will not leak outside.

The electromagnetic field supply apparatus 210 has a high-frequency power supply 211 which generates the microwaves MW, the RLSA 212, and a coaxial waveguide 213 which connects the high-frequency power supply 211 and RLSA 212 to each other.

The RLSA 212 has two parallel circular conductive plates 222 and 223 which form a radial waveguide 221, and a conductor ring 224 which connects the outer portions of the two conductive plates 222 and 223 so that they are shielded. An opening 225 for introducing the microwaves MW from the coaxial waveguide 213 into the radial waveguide 221 is formed at the center of the conductive plate 222 serving as the upper surface of the radial waveguide 221. A plurality of slots 226, through which the microwaves MW propagating in the radial waveguide 221 are supplied into the processing vessel 1, are formed in the conductive plate 223 serving as the lower surface of the radial waveguide 221.

The coaxial waveguide 213 is comprised of an outer conductor 213A and inner conductor 213B disposed coaxially. The outer conductor 213A is connected to the periphery of the opening 225 in the conductive plate 222 of the RLSA 212, and the inner conductor 213B extends through the opening 225 and is connected to the center of the conductive plate 223 of the RLSA 212.

In this arrangement, the microwaves MW generated by the high-frequency power supply 211 are introduced into the radial waveguide 221 through the coaxial waveguide 213. The microwaves MW propagate in the radial waveguide 221 radially, and are supplied into the processing vessel 1 from the slots 226 through the dielectric plate 7. In the processing vessel 1, the plasma gas introduced from the gas introducing nozzle 6 is ionized and sometimes dissociated by the electromagnetic field of the microwaves MW. Thus, the plasma P is generated to process the substrate 4.

FIG. 21 is a view showing another arrangement of the conventional microwave plasma processing apparatus. FIG. 22 is an enlarged sectional view of part of the arrangement (the connecting portion of the cylindrical waveguide and radial waveguide) of FIG. 21.

The plasma processing apparatus shown in FIG. 21 has a processing vessel 101 which accommodates a substrate 104 as a target object and processes the substrate 104 with a plasma, and an electromagnetic field supply apparatus 310 which supplies microwaves MW into the processing vessel 101 and generates a plasma P in the processing vessel 101 by the operation of the electromagnetic field of the microwaves MW.

The processing vessel 101 is a bottomed cylinder with an upper opening. A substrate table 103 is fixed to the central portion of the bottom surface of the processing vessel 101 through an insulating plate 102. The substrate 104 is arranged on the upper surface of the substrate table 103. Exhaust ports 105 for vacuum evacuation are formed in the periphery of the bottom surface of the processing vessel 101. A gas introducing nozzle 106 is arranged in the side wall of the processing vessel 101 to introduce a gas into the processing vessel 101. For example, when the plasma processing apparatus is used as an etching apparatus, a plasma gas such as Ar and etching gas such as CF₄ are introduced into it through the gas introducing nozzle 106.

The upper opening of the processing vessel 101 is sealed with a dielectric plate 107 so the plasma P generated in the processing vessel 101 does not leak outside. An RLSA 312 of the electromagnetic field supply apparatus 310 (to be described later) is disposed on the dielectric plate 107. The RLSA 312 is isolated from the processing vessel 101 by the dielectric plate 107, and is accordingly protected from the plasma P generated in the processing vessel 101. The outer surfaces of the dielectric plate 107 and RLSA 312 are covered by a shield material 108 arranged annularly on the side wall of the processing vessel 101. Thus, the microwaves MW will not leak outside.

The electromagnetic field supply apparatus 310 has a high-frequency power supply 211 which generates the microwaves MW, the RLSA 312, and a coaxial waveguide 313 which connects the high-frequency power supply 211 and RLSA 312 to each other.

The RLSA 312 has two circular conductive plates 322 and 323 which are arranged opposite to each other to form the radial waveguide 321, and a conductor ring 324 which connects the outer portions of the two conductive plates 322 and 323 so that they are shielded. An opening 325 to be connected to the cylindrical waveguide 313 is formed at the center of the conductive plate 322 serving as the upper surface of the radial waveguide 321. The microwaves MW are introduced into a radial waveguide 321 through the opening 325. A plurality of slots 326, through which the microwaves MW propagating in the radial waveguide 321 are supplied into the processing vessel 101, are formed in the conductive plate 323 serving as the lower surface of the radial waveguide 321.

A bump 327 made of aluminum is arranged at the center on the conductive plate 323. The bump 327 is a substantially circular conical member projecting toward the opening 325 of the conductive plate 322. The bump 327 moderates a change in impedance from the cylindrical waveguide 313 to the radial waveguide 321, so that reflection of the microwaves MW at the connecting portion of the cylindrical waveguide 313 and radial waveguide 321 can be decreased. When a diameter Lg of the cylindrical waveguide 313 is 90 mm, a height D of the radial waveguide 321 is 15 mm, and a use frequency f is 2.45 GHz, to obtain a reflectance (=reflected power/input power) of about −15 dB, for example, a diameter Lb of the bottom surface of the bump 327 must be set to 70 mm, and a height Hb of the bump 327 must be set to 50 mm.

A plurality of support columns 328 made of a ceramic material are arranged around the opening 325 of the conductive plate 322. The support columns 328 are fastened to both the conductive plates 322 and 323 with screws. The support columns 328 prevent the conductive plate 323 from bending with the loads of the bump 327 and of the conductive plate 323 itself.

In the coaxial waveguide 213 used in the conventional electromagnetic field supply apparatus 210, however, transmission power is readily converted into heat, and accordingly the transmission loss is large, so that the supply efficiency of the electromagnetic power is low. Hence, the conventional plasma processing apparatus using the electromagnetic field supply apparatus 210 has low generation efficiency of the plasma P.

When high power is input to the coaxial waveguide 213 and the inner conductor 213B is overheated accordingly, the heat of the inner conductor 213B deforms the conductive plate 223 of the RLSA 212 at the connection with the inner conductor 213B. As a result, a gap is formed between the inner conductor 213B and conductive plate 223 to cause abnormal discharge. To prevent this, a cooling mechanism must be provided in the thin inner conductor 213B. This, however, makes the structure complicated and increases the cost. Hence, with the conventional plasma processing apparatus, it is difficult to obtain stable operation at a low cost.

The bump 327 used in the conventional electromagnetic field supply apparatus 310 has a large mass, and accordingly the load acting on the conductive plate 323 serving as the lower surface of the radial waveguide 321 is large. Therefore, for example, when the RLSA 312 strikes something during assembly and an impact is applied to it, the support columns 328 which support the conductive plate 323 are damaged often.

To suppress the damage of the support columns 328, the support columns 328 may be formed thick so that their strengths are increased. Even when the support columns 328 is made of a ceramic material, if they are formed excessively thick, their influence on the electromagnetic field in the radial waveguide 321 cannot be neglected.

### SUMMARY OF THE INVENTION

The present invention has been made to solve the above problems, and has as its object to improve the electromagnetic field supply efficiency.

It is another object of the present invention to suppress any damage to the support columns without adversely affecting the electromagnetic field in the waveguide largely.

In order to achieve the above objects, an electromagnetic field supply apparatus according to the present invention is characterized by comprising a waveguide including a first conductive plate having a plurality of slots and a second conductive plate arranged opposite to the first conductive plate, a cylindrical waveguide connected to an opening of the second conductive plate, and a bump provided on the first conductive plate and projecting toward the opening of the second conductive plate, at least part of the bump being made of a dielectric.

In the electromagnetic field supply, a remaining part of the bump may be made of a metal. The distal end of the bump which is directed to the opening may be rounded. A connecting portion of the cylindrical waveguide and waveguide consisting of the two conductive plates may have a taper portion spreading from the cylindrical waveguide toward the waveguide. Support columns may be disposed around the opening of the second conductive plate, fastened to the first and second conductive plates, and made of a dielectric.

An electromagnetic field supply apparatus according to the present invention is characterized by comprising a waveguide including a first conductive plate having a plurality of slots and a second conductive plate arranged opposite to the first conductive plate, and a cylindrical waveguide connected to an opening of the second conductive plate, wherein a connecting portion of the cylindrical waveguide and waveguide has a taper portion spreading from the cylindrical waveguide toward the waveguide.

The electromagnetic field supply apparatus may comprise a bump provided on the first conductive plate and projecting toward the opening of the second conductive plate. The bump may be made of a metal. The distal end of the bump which is directed to the opening may be rounded. Support columns may be disposed around the opening of the second conductive plate, fastened to the first and second conductive plates, and made of a dielectric.

An electromagnetic field supply apparatus according to the present invention is characterized by comprising a waveguide including a first conductive plate having a plurality of slots and a second conductive plate arranged opposite to the first conductive plate, a cylindrical waveguide connected to an opening of the second conductive plate, and a bump provided on the first conductive plate and projecting toward the opening of the second conductive plate, wherein the bump comprises a bump main body made of a dielectric and a metal film covering a surface of the bump main body.

In this electromagnetic field supply apparatus, a connecting portion of the cylindrical waveguide and waveguide may have a taper portion spreading from the cylindrical waveguide toward the waveguide. The distal end of the bump which is directed to the opening may be rounded. Support columns may be disposed around the opening of the second conductive plate, fastened to the first and second conductive plates, and made of a dielectric.

In order to achieve the objects described above, a plasma processing apparatus according to the present invention is characterized by comprising a processing vessel which accommodates a target object, and an electromagnetic field supply apparatus which supplies an electromagnetic field into the processing vessel, wherein the electromagnetic field supply apparatus described above is used as the electromagnetic field supply apparatus.

### BRIEF DESCRIPTION OF DRAWINGS

FIG. 1 is a view showing the arrangement of the first embodiment of the present invention;

FIG. 2 is a plan view of a conductive plate serving as the lower surface of the radial waveguide seen from the direction of the line II-II′ of FIG. 1;

FIG. 3 is a conceptual view showing a desirable side surface shape of a bump;

FIG. 4 is a view showing an arrangement of a circular polarization converter;

FIG. 5 is a conceptual view showing the state of propagation of the microwaves at the connecting portion of a cylindrical waveguide and the radial waveguide;

FIG. 6 is a view for explaining the distribution of the microwaves in the radial waveguide;

FIGS. 7A to 7C are sectional views showing modifications of the bump;

FIGS. 8A to 8C are sectional views showing modifications of the bump;

FIG. 9 is a plan view showing a modification of the bump;

FIG. 10 is a sectional view showing the arrangement of the main part of the second embodiment of the present invention;

FIG. 11 is a view showing the arrangement of the third embodiment of the present invention;

FIG. 12 is a view showing an arrangement of a circular polarization converter;

FIG. 13 is an enlarged sectional view of a radial line slot antenna;

FIG. 14 is a plan view of a conductive plate serving as the lower surface of the radial waveguide seen from the direction of the line XIV-XIV′ of FIG. 13;

FIG. 15 is a conceptual view showing a desired side surface shape of a bump;

FIG. 16 is a conceptual view showing the state of propagation of microwaves at the connecting portion of a cylindrical waveguide and the radial waveguide;

FIG. 17 is a view for explaining the distribution of the microwaves in the radial waveguide;

FIG. 18 is a sectional view showing the arrangement of the main part of the fourth embodiment of the present invention;

FIG. 19 is a sectional view showing the arrangement of the main part of the fifth embodiment of the present invention;

FIG. 20 is a view showing an arrangement of a conventional plasma processing apparatus;

FIG. 21 is a view showing another arrangement of the conventional microwave plasma processing apparatus; and

FIG. 22 is an enlarged sectional view of the connecting portion of a cylindrical waveguide and radial waveguide.

### DESCRIPTION OF THE PREFERRED EMBODIMENTS

The embodiments of the present invention will be described in detail with reference to the drawings.

First Embodiment

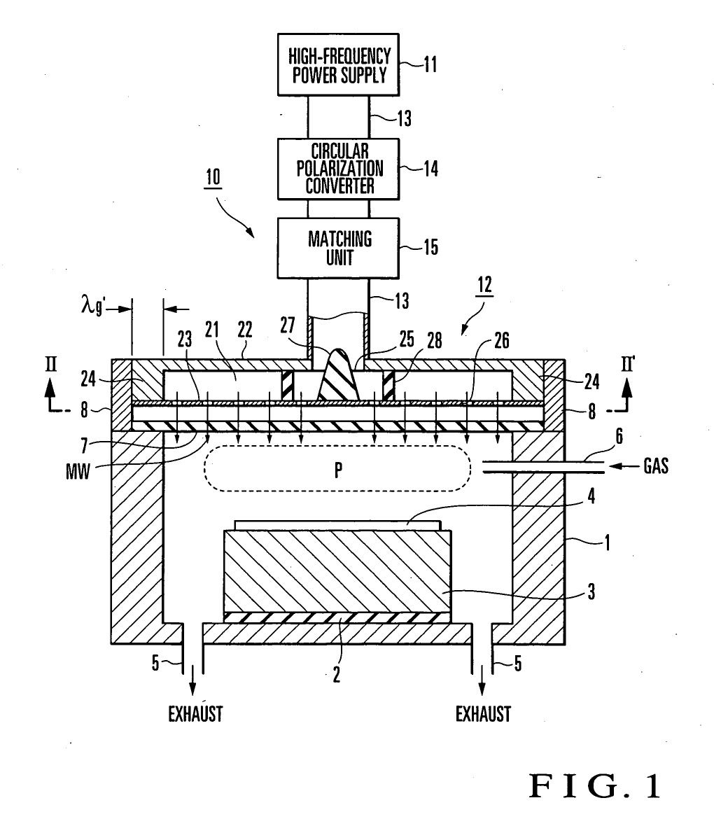

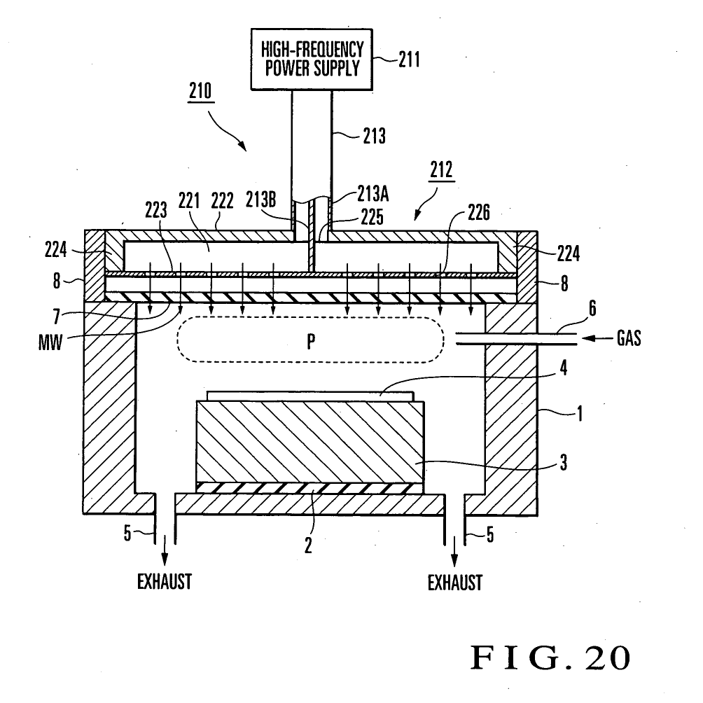

FIG. 1 is a view showing the arrangement of the first embodiment of the present invention. In FIG. 1, the same or identical portions as in FIG. 20 are denoted by the same reference numerals, and a description thereof will accordingly be omitted.

The plasma processing apparatus shown in FIG. 1 has a processing vessel 1 which accommodates a substrate 4, e.g., a semiconductor or LCD, as a target object and processes the substrate 4 with a plasma, and an electromagnetic field supply apparatus 10 which supplies microwaves MW into the processing vessel 1 so that a plasma P is generated in the processing vessel 1 by the operation of the electromagnetic field of the microwaves MW.

The electromagnetic field supply apparatus 10 has a high-frequency power supply 11 which generates the microwaves MW with a frequency of 2.45 GHz, a radial line slot antenna (to be abbreviated as RLSA hereinafter) 12, and a cylindrical waveguide 13 which connects the high-frequency power supply 11 and RLSA 12 to each other. The transmission frequency of the cylindrical waveguide 13 is 2.45 GHz, and the transmission mode of the cylindrical waveguide 13 is TE₁₁.

The RLSA 12 is comprised of two opposing circular conductive plates 22 and 23 which form a radial waveguide 21, and a conductor ring 24 which connects the outer surfaces of the two conductive plates 22 and 23 so that they are shielded.

The position of the inner surface of the conductor ring 24 is substantially the same as the position in the radial direction of the inner surface of the side wall of the processing vessel 1. The length of the difference between the position of the inner surface of a shield material 8 and the position in the radial direction of the inner surface of the side wall of the processing vessel 1 is substantially the same as a wavelength λg′ of the microwaves MW in the space formed by the lower surface of the conductive plate 23, the upper surface of the side wall of the processing vessel 1, and the inner surface of the shield material 8, or can be different from it.

An opening 25 to be connected to the cylindrical waveguide 14 is formed at the center of the conductive plate 22 serving as the upper surface of the radial waveguide 21. The microwaves MW are introduced into the radial waveguide 21 through the opening 25. A plurality of slots 26, through which the microwaves MW propagating in the radial waveguide 21 are supplied into the processing vessel 1, are formed in the conductive plate 23 serving as the lower surface of the radial waveguide 21.

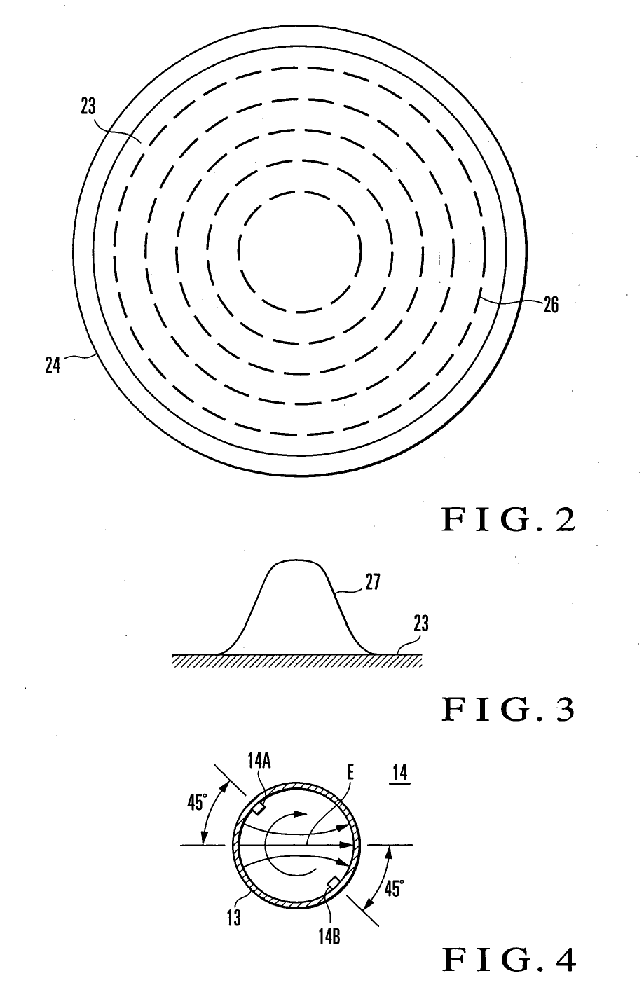

FIG. 2 is a plan view showing an example of the slot arrangement on the conductive plate 23. As shown in FIG. 2, the slots 26 may be concentrically arranged on the conductive plate 23 to extend in the circumferential direction of the conductive plate 23. Alternatively, the slots 26 may be arranged to form swirls. The slot interval in the radial direction of the conductive plate 23 may be set to about λg (λg is a tube wavelength in the radial waveguide 21) so that a radial antenna is formed, or about λg/3 to λg/40 so that a leakage antenna is formed. Alternatively, a plurality of pairs of slots 26 in which each pair forms an inverted-V shape may be arranged, so that a circular polarized wave is radiated.

A dielectric having relative dielectric constant larger than 1 may be arranged in the radial waveguide 21. This decreases the tube wavelength λg. Thus, the number of slots 26 to be arranged in the radial direction of the conductive plate 23 may be increased, so that the supply efficiency of the microwaves MW may be improved.

As shown in FIG. 1, a bump 27 made of a dielectric is provided at the center on the conductive plate 23. The bump 27 is a substantially circular conical member projecting toward the opening 25 of the conductive plate 22. The bump 27 is desirably made of a dielectric having relative dielectric constant of 10 or more, but its relative dielectric constant may be smaller than 10. With the bump 27, a change in impedance from the cylindrical waveguide 13 to the radial waveguide 21 is moderated, and accordingly the reflection of the microwaves MW at the connecting portion of the cylindrical waveguide 13 and radial waveguide 21 can be decreased. For example, assuming that the substantially circular conical bump 27 is made of a dielectric having relative dielectric constant εr=20 and that the diameter and height of the bottom surface of the bump 27 are 70 mm and 48 mm, respectively, a good simulation result is obtained, that is, the reflectance (reflected power/incident power) is about 20 dB or less.

FIG. 3 is a conceptual view showing a desirable side surface shape of the bump 27. As shown in FIG. 3, when the distal end of the bump 27 is rounded substantially spherically, concentration of the electric field on the distal end of the bump 27 to cause abnormal discharge can be suppressed. When the inclination of the ridge line of the foot portion of the bump 27 with respect to the conductive plate 23 is decreased, the impedance change at the boundary of the bump 27 and conductive plate 23 can be decreased, so that the reflection of the microwaves MW at the boundary can be decreased.

As shown in FIG. 1, a plurality of support columns 28 each made of a dielectric are arranged around the opening 25 of the conductive plate 22. The support columns 28 are fastened to both the conductive plates 22 and 23, so they prevent the conductive plate 23 from bending with the load of the bump 27.

In the cylindrical waveguide 13, a circular polarization converter 14 is provided to the high-frequency power supply 11 side, and a matching unit 15 is provided to the RLSA 12 side.

The circular polarization converter 14 converts the TE₁₁-mode microwaves MW propagating in the cylindrical waveguide 13 into circular polarized waves. The circular polarized waves are electromagnetic waves whose field vectors form a rotating field that makes a turn in one period on a plane perpendicular to an axis in the traveling direction.

FIG. 4 is a view showing an arrangement of the circular polarization converter 14, and shows a section perpendicular to the axis of the cylindrical waveguide 13. The circular polarization converter 14 shown in FIG. 4 is obtained by forming, on the inner wall surface of the cylindrical waveguide 13, two opposing cylindrical projections 14A and 14B that form a pair, or a plurality of pairs of such cylindrical projections 14A and 14B in the axial direction of the cylindrical waveguide 13. The two cylindrical projections 14A and 14B are arranged in a direction to form 45° with respect to the main direction of an electric field E of the TE₁₁-mode microwaves MW. A circular polarization converter having another arrangement may be used instead.

The matching unit 15 matches the impedance of the supply side (i.e., the high-frequency power supply 11 side) and that of the load side (i.e., the RLSA 12 side) of the cylindrical waveguide 13. As the matching unit 15, for example, one obtained by arranging four sets of reactance elements, each set including a plurality of reactance elements arranged in the axial direction of the cylindrical waveguide 13, with an angular interval of 90° in the circumferential direction of the cylindrical waveguide 13 can be used. As the reactance element, a stub made of a conductor or dielectric projecting in the radial direction from the inner wall surface of the cylindrical waveguide 13, a branch waveguide having one end which is open to the interior of the cylindrical waveguide 13 and the other end which is electrically short-circuited, or the like can be used.

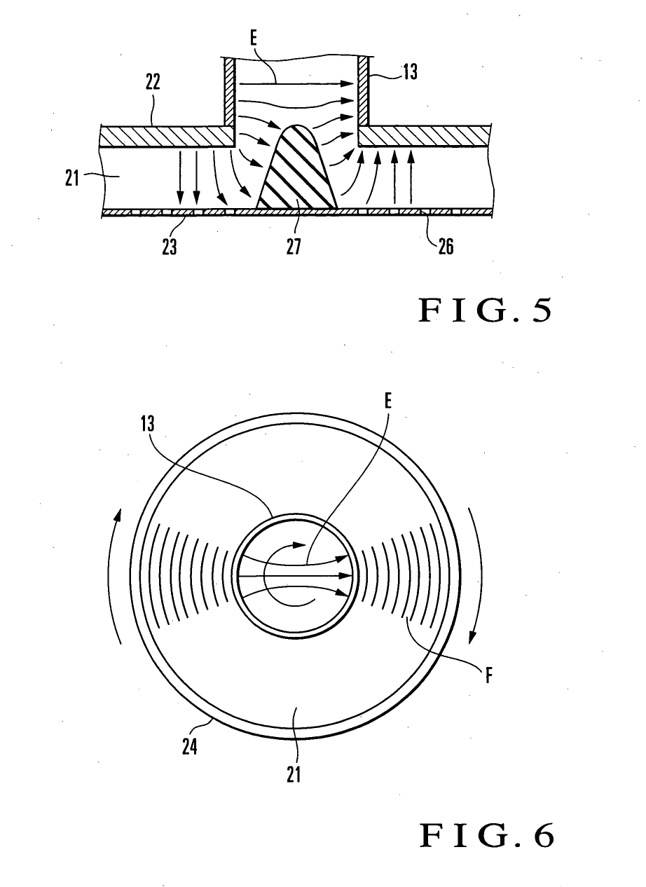

The operation of the plasma processing apparatus shown in FIG. 1 will be described. FIG. 5 is a conceptual view showing the state of propagation of the microwaves MW at the connecting portion of the cylindrical waveguide 13 and radial waveguide 21.

The microwaves MW generated in the high-frequency power supply 11 are converted into a circular polarized wave by the circular polarization converter 14 provided to the cylindrical waveguide 13, and propagates toward the radial waveguide 21. As the microwaves MW propagate in the cylindrical waveguide 13 with the TE₁₁ mode, the direction of the electric field E of the microwaves MW is “horizontal” perpendicular to the axis of the cylindrical waveguide 13. Once the microwaves MW reach the connecting portion of the cylindrical waveguide 13 and radial waveguide 21, due to the presence of the bump 27, the direction of their electric field E gradually changes to a “perpendicular direction” perpendicular to the conductive plates 22 and 23, as shown in FIG. 5. The microwaves MW introduced into the radial waveguide 21 then propagate in the radial direction with the TE mode.

The microwaves MW propagating in the radial waveguide 21 are supplied into the processing vessel 1 through a dielectric plate 7 via the plurality of slots 26 formed in the conductive plate 23 serving as the lower surface of the radial waveguide 21. In the processing vessel 1, the electromagnetic field of the microwaves MW ionizes or sometimes dissociates the plasma gas introduced from a nozzle 6. Thus, the plasma P is generated and processes the substrate 4.

The effect obtained with the plasma processing apparatus shown in FIG. 1 will be described.

The electromagnetic field supply apparatus 10 generally uses the cylindrical waveguide 13 with large characteristic impedance. According to the JIS standards, while the characteristic impedance of a coaxial waveguide 213 for 2.45 GHz is 50 Ω, that of the cylindrical waveguide 13 for the same frequency is as large as 500 Ω to 600 Ω. Hence, the wall surface current generated when the same power is supplied is smaller in the cylindrical waveguide 13 than in the coaxial waveguide 213. The smaller the wall surface current, the smaller the transmission loss caused by conversion of the transmission power into heat. Therefore, when the cylindrical waveguide 13 having a relatively small wall surface current is used, the transmission loss can be decreased.

When the bump 27 made of a dielectric is provided, a change in impedance from the cylindrical waveguide 13 to the radial waveguide 21 can be moderated, so that the reflection of the power at the connecting portion of the cylindrical waveguide 13 and radial waveguide 21 can be decreased.

In this manner, when the transmission loss and power reflection are decreased, the supply efficiency of the electromagnetic field with the electromagnetic field supply apparatus 10 can be improved. Furthermore, when the plasma processing apparatus is formed using the electromagnetic field supply apparatus 10, the generation efficiency of the plasma P can be improved.

As the cylindrical waveguide 13 used in the electromagnetic field supply apparatus 10 has no inner conductor 213B unlike in the coaxial waveguide 213, abnormal discharge caused by overheating of the inner conductor does not occur. The cylindrical waveguide 13 has the bump 27. As the heat generation amount of the cylindrical waveguide 13 is smaller than that of the coaxial waveguide 213, even if high power is supplied to the cylindrical waveguide 13, abnormal discharge caused by overheating of the bump 27 with the heat from the cylindrical waveguide 13 does not likely to occur. Hence, a complicated structure such as a cooling mechanism need not be provided to prevent abnormal discharge. As a result, the stable operation of the electromagnetic field supply apparatus 10 and of the plasma processing apparatus can be realized at a low cost.

The microwaves MW propagate in the cylindrical waveguide 13 with the TE₁₁mode. Thus, the field strength distribution in the radial waveguide 21 becomes as shown in FIG. 6, where a portion F with high field strength is unevenly distributed in the direction of the electric field E in the cylindrical waveguide 13. However, as the microwaves MW propagating in the cylindrical waveguide 13 are circular polarized waves and the electric field E of the microwaves MW rotates about the axis of the cylindrical waveguide 13 as the center, the portion F with the high field strength in the radial waveguide 21 also rotates. Therefore, the field strength distribution in the radial waveguide 21 is uniformed as a time average. The field strength distribution in the processing vessel 1 is also uniformed as a time average. Thus, a uniform process can be performed within the surface of the substrate 4 by using the plasma P generated by the electromagnetic field in the processing vessel 1.

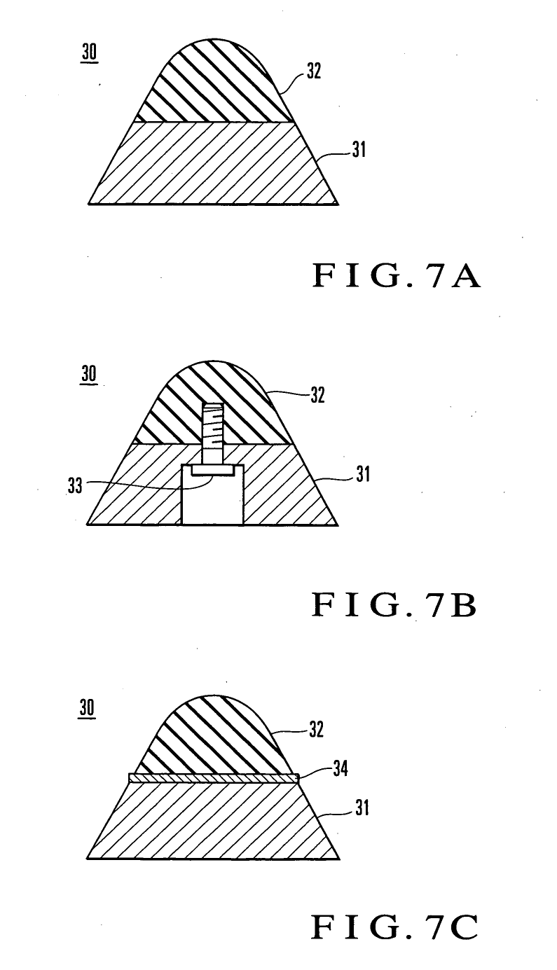

Modifications of the bump 27 will be described. FIGS. 7A to 7C, FIGS. 8A to 8C, and FIG. 9 show modifications of the pump.

While the bump 27 shown in FIG. 1 is made of only a dielectric, a bump 30 shown in FIG. 7A has a two-layered structure including a lower layer 31 made of a metal such as aluminum or copper and an upper layer 32 made of a dielectric.

To bond the upper layer 32 to the lower layer 31, for example, the upper layer 32 and lower layer 31 may be fastened to each other with a bolt 33, as shown in FIG. 7B. The bolt 33 is desirably made of a dielectric. Alternatively, as shown in FIG. 7C, a thin metal film 34 may be formed on the lower surface of the upper layer 32 made of the dielectric, and the upper layer 32 and lower layer 31 may be thermally bonded to each other. In this case, a brazing material may be used. When the thin metal film 34 is made of a material having high thermal conductivity, heat generated by the upper layer 32 can be dissipated to the conductive plate 23 through the lower layer 31, so that overheating of the bump 30 may be prevented.

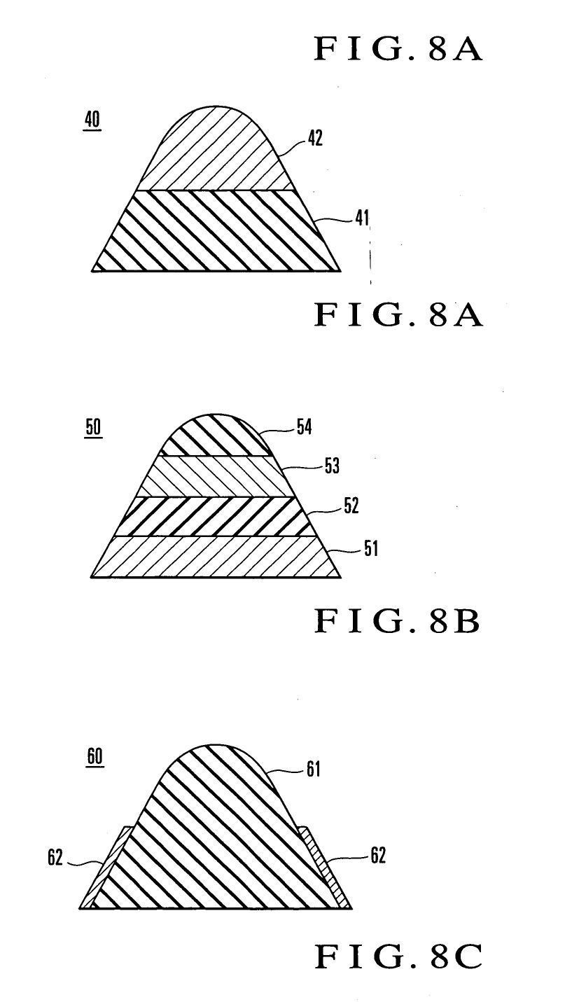

As in a bump 40 shown in FIG. 8A, a lower layer 41 may be made of a dielectric, and an upper layer 42 may be made of a metal.

As in a bump 50 shown in FIG. 8B, layers 51 and 53 made of metals and layers 52 and 54 made of dielectrics may be arranged alternately to form a multilayered structure.

As in a bump 60 shown in FIG. 8C, a bump main body 61 may be made of a dielectric, and the surface of the bump main body 61 may be covered with a thin metal film 62 partly or entirely.

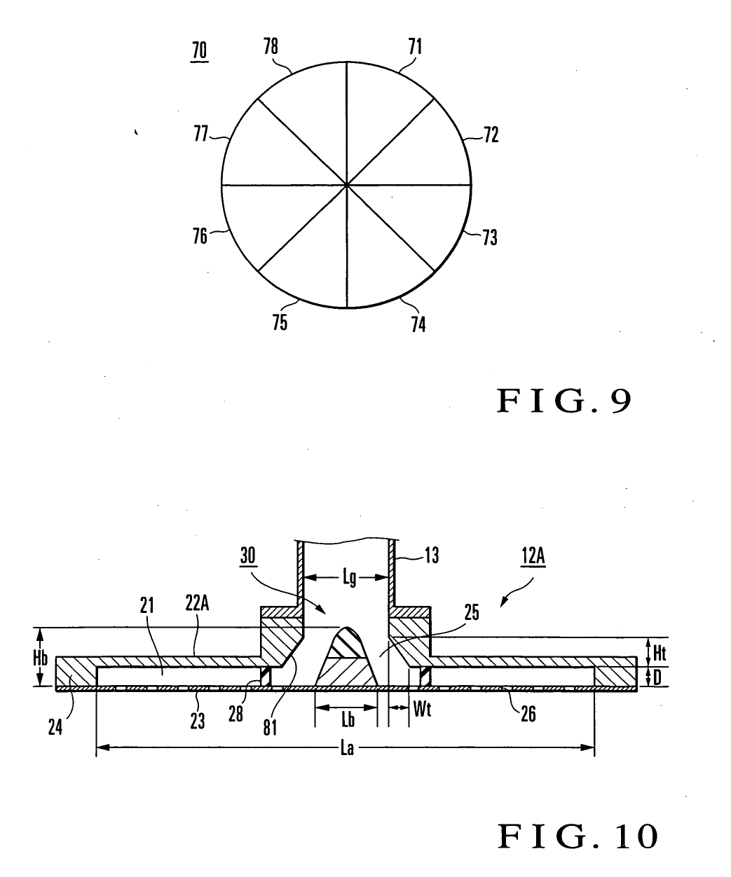

As in a bump 70 shown in FIG. 9, the bump may be divided by planes including the axis of the bump 70 into portions 71, 73, 75, and 77 made of metals and portions 72, 74, 76, and 87 made of dielectrics.

In this manner, the pump need not always be made of only a dielectric, but can be partly made of a metal. When the pump is partly made of a metal, a less expensive dielectric having low relative dielectric constant can be used. As a result, the manufacturing cost of the pump can be reduced.

Second Embodiment

FIG. 10 is a sectional view showing the arrangement of the main part of the second embodiment of the present invention. In FIG. 10, the same or identical portions as in FIG. 1 and FIGS. 7A to 7C are denoted by the same reference numerals, and a description thereof will accordingly be omitted.

The electromagnetic field supply apparatus shown in FIG. 10 has, at its connecting portion of a cylindrical waveguide 13 and radial waveguide 21, a taper portion 81 spreading from the cylindrical waveguide 13 toward a conductive plate 22A. A bump 30 constituted by a lower layer 31 made of a metal and an upper layer 32 made of a dielectric is arranged at the center on a conductive plate 23.

As in this electromagnetic field supply apparatus, when the bump 30 is provided and the taper portion 81 is formed at the connecting portion of the cylindrical waveguide 13 and radial waveguide 21, the impedance change from the cylindrical waveguide 13 to the radial waveguide 21 can be further moderated, so that the reflection of the power at the connecting portion of the cylindrical waveguide 13 and radial waveguide 21 can be further decreased.

A simulation result of the reflectance of this electromagnetic field supply apparatus will be described. In this simulation, a diameter Lg of the cylindrical waveguide 13 was set to 90 mm, and a diameter La and height D of the radial waveguide 21 were set to 480 mm and 15 mm, respectively. A difference Wt between the radius of the bottom surface of the taper portion 81 and the radius (Lg/2) of the cylindrical waveguide 13 was set to 5 mm, and a height Ht of the taper portion 81 was set to 5 mm. A diameter Lb of the bottom surface of the bump 30 and a height Hb of the bump 30 were set to 70 mm and 50 mm, respectively. The lower layer 31 of the bump 30 was formed of aluminum, and its upper layer 32 was formed of BaTiO₃ (barium titanate: with relative dielectric constant εr=13 to 15, tan δ=10⁻⁴ at 2.45 GHz). In this arrangement, when microwaves MW having a frequency of 2.45 GHz were supplied from a high-frequency power supply 11, the reflectance was as very small as −30 dB to −25 dB. Hence, this electromagnetic field supply apparatus has high electromagnetic field supply efficiency. When this electromagnetic field supply apparatus is used in the plasma processing apparatus, a plasma can be generated efficiently.

In the above description, the microwave MW having a frequency of 2.45 GHz is used. The frequency that can be used is not limited to 2.45 GHz. The same effect can be obtained with e.g., a microwave having a frequency of 1 GHz to ten-odd GHz. Furthermore, the same effect can also be obtained when a high frequency including a frequency band lower than the microwave is used.

The transmission mode of the microwave MW can be TM₀₁ mode.

Although the slot antenna was exemplified by the RLSAs 12 and 12A, the slot antenna is not limited to them, but another slot antenna can be employed.

Third Embodiment

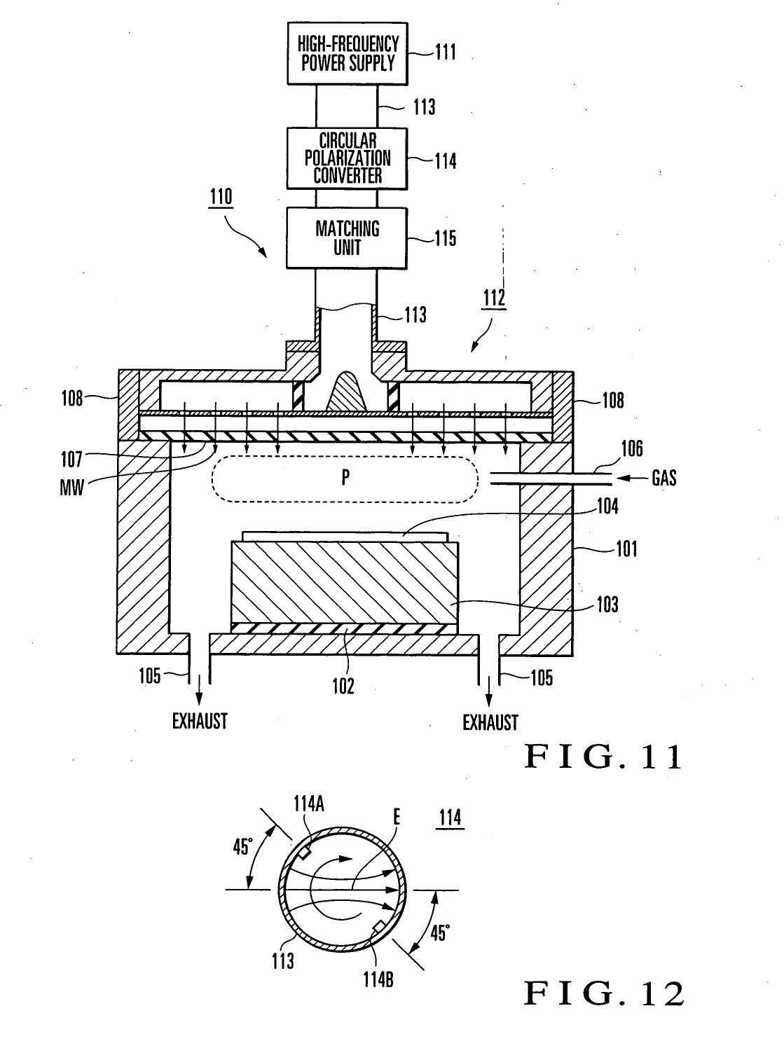

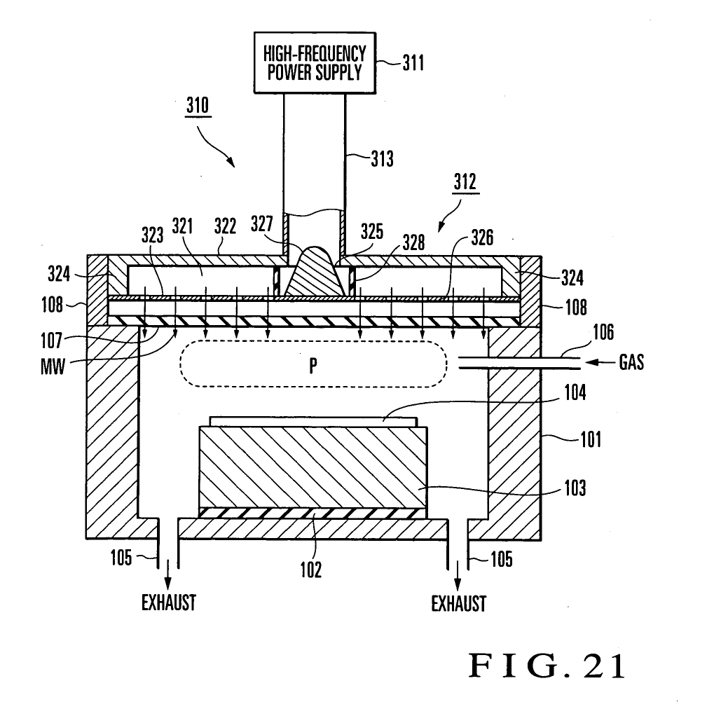

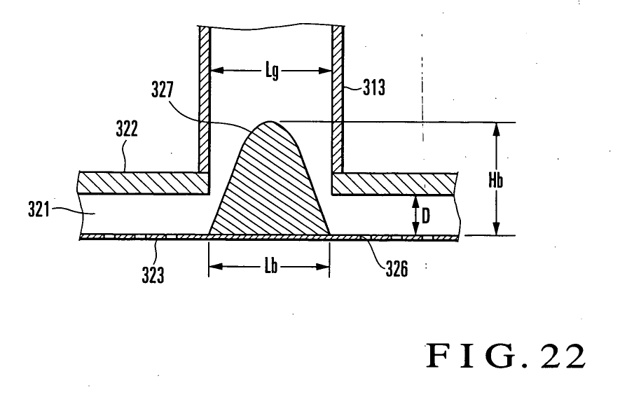

FIG. 11 is a view showing the arrangement of the third embodiment of the present invention. In FIG. 11, the same or identical portions as in FIG. 21 are denoted by the same reference numerals, and a detailed description thereof will accordingly be omitted.

The plasma processing apparatus shown in FIG. 11 has a processing vessel 101 which accommodates a substrate (target object) 104, e.g., a semiconductor or LCD, and processes the substrate 104 with a plasma, and an electromagnetic field supply apparatus 110 which supplies microwaves MW into the processing vessel 101 so that a plasma P is generated in the processing vessel 101 by the operation of the electromagnetic field of the microwaves MW.

The electromagnetic field supply apparatus 110 has a high-frequency power supply 111 which generates the microwaves MW with a frequency of 2.45 GHz, a radial line slot antenna (to be abbreviated as RLSA hereinafter) 112, and a cylindrical waveguide 113 which connects the high-frequency power supply 111 and RLSA 112 to each other. The transmission frequency of the cylindrical waveguide 113 is 2.45 GHz, and its transmission mode is TE₁₁.

In the cylindrical waveguide 113, a circular polarization converter 114 is provided on the high-frequency power supply 11 side, and a matching unit 115 is provided on the RLSA 112 side.

The circular polarization converter 114 converts the TE₁₁-mode microwaves MW propagating in the cylindrical waveguide 113 into circular polarized waves. Circular polarized waves are electromagnetic waves whose field vectors form a rotating field that makes a turn in one period on a plane perpendicular to an axis in the traveling direction.

FIG. 12 is a view showing an arrangement of the circular polarization converter 114, and shows a section perpendicular to the axis of the cylindrical waveguide 113. The circular polarization converter 114 shown in FIG. 12 is obtained by forming, on the inner wall surface of the cylindrical waveguide 113, two opposing cylindrical projections 114A and 114B that form a pair, or a plurality of pairs of such cylindrical projections 114A and 114B in the axial direction of the cylindrical waveguide 113. The two cylindrical projections 114A and 114B are arranged in a direction to form 45° with respect to the main direction of an electric field E of the TE₁₁-mode microwaves MW. A circular polarization converter having another arrangement may be used instead.

The matching unit 115 matches the impedance of the supply side (i.e., the high-frequency power supply 111 side) and that of the load side (i.e., the RLSA 112 side) of the cylindrical waveguide 113. As the matching unit 115, for example, one obtained by arranging four sets of reactance elements, each set including a plurality of reactance elements arranged in the axial direction of the cylindrical waveguide 113, with an angular interval of 90° in the circumferential direction of the cylindrical waveguide 113 can be used. As the reactance element, a stub made of a conductor or dielectric and projecting in the radial direction from the inner wall surface of the cylindrical waveguide 113, a branch waveguide having one end which is open to the interior of the cylindrical waveguide 113 and the other end which is electrically short-circuited, or the like can be used.

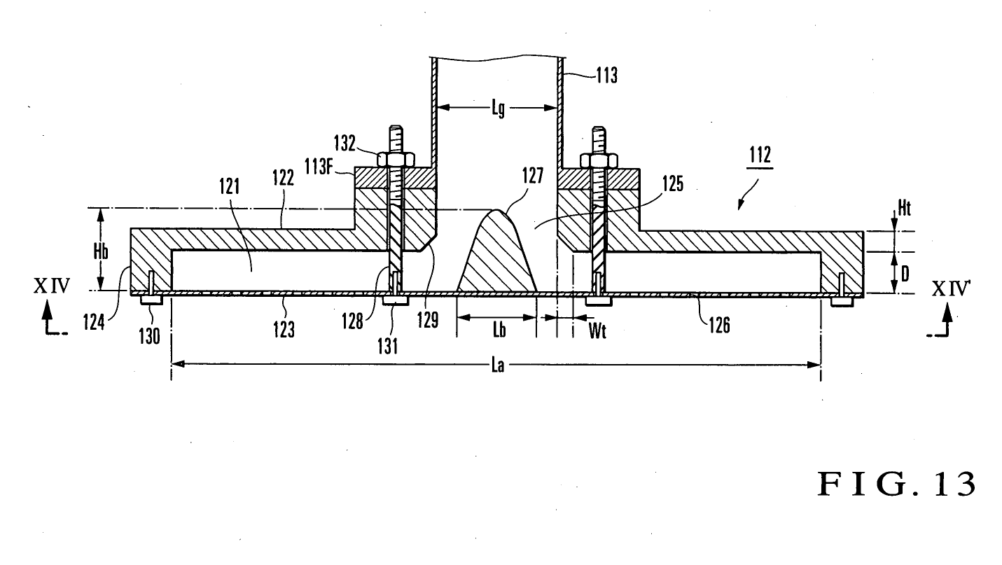

FIG. 13 is an enlarged sectional view of the RLSA 112 shown in FIG. 11. The RLSA 112 is comprised of two opposing conductive plates 122 and 123 which form a radial waveguide 121, and a conductor ring 124 which connects the outer portions of the two conductive plates 122 and 123 so that they are shielded. The conductor ring 124 and the conductive plate 122 which serves as the upper surface of the radial waveguide 121 are integrally formed, and the conductive plate 123 which serves as the lower surface of the radial waveguide 121 is fastened to the conductor ring with bolts 130.

A circular opening 125 is formed at the center of the conductive plate 122 serving as the upper surface of the radial waveguide 121, and a flange 113F of the cylindrical waveguide 113 is fastened to the periphery of the opening 125 with bolts (not shown). Thus, the cylindrical waveguide 113 and radial waveguide 121 are connected to each other, and the microwaves MW propagating in the cylindrical waveguide 113 are introduced into the radial waveguide 121 through the opening 125.

A plurality of slots 126, through which the microwaves MW propagating in the radial waveguide 121 are supplied into the processing vessel 101, are formed in the conductive plate 123 serving as the lower surface of the radial waveguide 121.

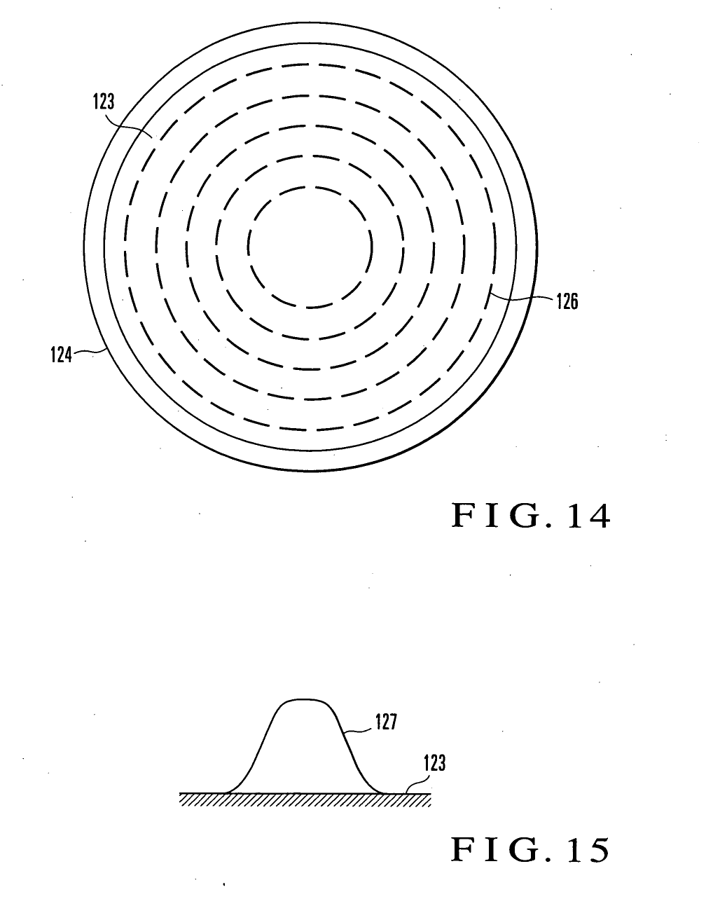

FIG. 14 is a plan view showing an example of the slot arrangement on the conductive plate 123. As shown in FIG. 14, the slots 126 may be concentrically arranged on the conductive plate 123 to extend in the circumferential direction of the conductive plate 123. Alternatively, the slots 126 may be arranged to form swirls. The slot interval in the radial direction of the conductive plate 123 may be set to about λg (λg is a tube wavelength in the radial waveguide 121) so that a radial antenna is formed, or about λg/3 to λg/40 so that a leakage antenna is formed. Alternatively, a plurality of pairs of slots 126 in which each pair forms an inverted-V shape may be arranged, so that circular polarized waves are radiated.

A dielectric having relative dielectric constant larger than 1 may be arranged in the radial waveguide 121. This decreases the tube wavelength λg. Thus, the number of slots 126 to be arranged in the radial direction of the conductive plate 123 may be increased, so that the supply efficiency of the microwaves MW may be improved.

As shown in FIG. 13, a taper portion 129 is formed at the connecting portion of the cylindrical waveguide 113 and radial waveguide 121 to spread from the cylindrical waveguide 113 toward the radial waveguide 121. The sectional shape of the taper may be linear or arcuate.

A bump 127 is provided at the center on the conductive plate 123. The bump 127 is a substantially circular conical member projecting toward the opening 125 of the conductive plate 122, and is made of a metal such as aluminum or copper.

FIG. 15 is a conceptual view showing a desirable side surface shape of the bump 127. As shown in FIG. 15, when the distal end of the bump 127 is rounded substantially spherically, concentration of the electric field on the distal end of the bump 127 to cause abnormal discharge can be suppressed. When the inclination of the ridge line of the foot portion of the bump 127 with respect to the conductive plate 123 is decreased, the impedance change at the boundary of the bump 127 and conductive plate 123 can be decreased, so that the reflection of the microwaves MW at the boundary can be decreased.

Due to the operations of the substantially circular conical bump 127 and taper portion 129 described above, the change in impedance from the cylindrical waveguide 113 to the radial waveguide 121 can be moderated, so that the reflection of the microwaves MW at the connecting portion of the cylindrical waveguide 113 and radial waveguide 121 can be decreased.

Furthermore, as shown in FIG. 13, a plurality of support columns 128 are arranged around the opening 125 of the conductive plate 122. Each support column 128 forms a cylinder as a whole and has a threaded portion on its upper outer portion and a screw hole in its lower surface. The support columns are inserted in rectangular through holes formed in the conductive plate 122 around the opening 125 and in the flange 113F of the cylindrical waveguide 113. With the lower surfaces of the support columns 128 being in contact with the conductive plate 123, bolts 131 are inserted in the screw holes of the support columns 128 from below the conductive plate 123. Thus, the support columns 128 are fastened to the conductive plate 123. Also, nuts 132 are inserted around the threaded portions projecting upward from the flange 113F, so that the support columns 128 are fastened to the conductive plate 122. In this manner, when the support columns 128 are fastened to both the conductive plates 122 and 123, the vicinity of the center of the conductive plate 123 is supported by the support columns 128, so that the conductive plate 123 is prevented from bending with the loads of the bump 127 and conductive plate 123 itself. Also, the support columns 128 and bolts 131 are made of a dielectric such as a ceramic material, so that an adverse influence on the electromagnetic field in the radial waveguide 121 is suppressed.

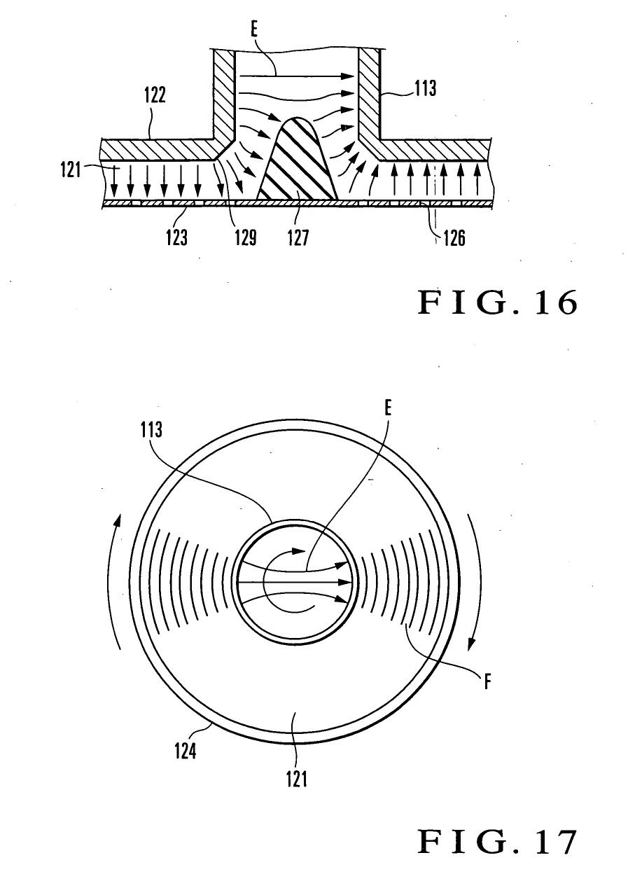

The operation of the plasma processing apparatus shown in FIGS. 11 to 15 will be described. FIG. 16 is a conceptual view showing the state of propagation of the microwave MW at the connecting portion of the cylindrical waveguide 113 and radial waveguide 121.

The microwaves MW generated by the high-frequency power supply 111 propagate in the cylindrical waveguide 113 with the TE₁₁ mode, are converted into circular polarized waves by the circular polarization converter 114, and reach the connecting portion of the cylindrical waveguide 113 and radial waveguide 121. At the connecting portion, as shown in FIG. 16, the microwaves MW are divided by the bump 127 into the left and right portions within the plane including the axis of the cylindrical waveguide 113. The direction of the electric field E that has been horizontal in the cylindrical waveguide 113 gradually inclines due to the bump 127 and taper portion 129, and finally changes to the perpendicular direction. In this manner, the microwaves MW introduced into the radial waveguide 121 propagate in the TE mode in the radial direction.

The microwaves MW propagating in the radial waveguide 121 are supplied into the processing vessel 101 through a dielectric plate 107 via the plurality of slots 126 formed in the conductive plate 123 serving as the lower surface of the radial waveguide 121. In the processing vessel 101, the electromagnetic field of the microwaves MW ionizes or sometimes dissociates the plasma gas introduced from a nozzle 106. Thus, the plasma P is generated and processes the substrate 104.

The microwaves MW propagate in the cylindrical waveguide 113 in the TE₁₁ mode. Thus, the field strength distribution in the radial waveguide 121 becomes as shown in FIG. 17, where a portion F with large field strength is unevenly distributed in the direction of the electric field E in the cylindrical waveguide 113. However, as the microwaves MW propagating in the cylindrical waveguide 113 are circular polarized waves and the electric field E of the microwaves MW rotates about the axis of the cylindrical waveguide 113 as the center, the portion F with the high field strength in the radial waveguide 121 also rotates. Therefore, the field strength distribution in the radial waveguide 121 is uniformed as a time average. The field strength distribution in the processing vessel 101 is also uniformed as a time average. Thus, a uniform process can be performed within the surface of the substrate 104 by using the plasma P generated by the electromagnetic field in the processing vessel 101.

A simulation result of the electromagnetic field supply apparatus 110 shown in FIG. 13 will be described. In this simulation, a diameter Lg of the cylindrical waveguide 113 was set to 90 mm, and a diameter La and height D of the radial waveguide 121 were set to 480 mm and 15 mm, respectively. A difference Wt between the radius of the bottom surface of the taper portion 129 and the radius (Lg/2) of the cylindrical waveguide 113 was set to 5 mm, and a height Ht of the taper portion 181 was set to 5 mm. The bump 127 was formed of aluminum, and a diameter Lb and height Hb of the bottom surface of the bump 127 were set to 85 mm and 30 mm, respectively. In this arrangement, a simulation was performed on the assumption that a microwaves MW having a frequency of 2.45 GHz were supplied to the cylindrical waveguide 113. The reflectance (reflected power/input power) at the connecting portion of the cylindrical waveguide 113 and radial waveguide 121 was −15 dB.

From this simulation result, if the taper portion 129 is formed in the electromagnetic field supply apparatus 110 shown in FIG. 13, the reflectance that is conventionally obtained with the bump 327 satisfying Lb=70 mm and Hb=50 mm can be obtained with the bump 127 having a smaller volume than the conventional bump and satisfying Lb=85 mm and Hb=30 mm. When the volume of the bump 127 is decreased, its mass can be decreased, and accordingly the load acting on the conductive plate 123 can be decreased. Thus, the frequency with which the support columns 128 that support the conductive plate, when an impact is applied to the RLSA 112, can be decreased.

In the electromagnetic field supply apparatus 110, the frequency with which the support columns 128 are damaged can be decreased without forming the support columns 128 thicker. Thus, the influence on the electromagnetic field in the radial waveguide 121 is small.

A similar simulation was performed by changing only the diameter Lb of the bottom surface of the bump 127. When the diameter Lb was 90 mm or more, the reflectance was −20 dB or less. From this result, when the taper portion 129 is formed to satisfy Wt=Ht=5 mm and the bump 127 satisfying Lb≧90 mm in diameter and Hb=30 mm in diameter is used, the reflectance at the connecting portion of the cylindrical waveguide 113 and radial waveguide 121 can be minimized.

Fourth Embodiment

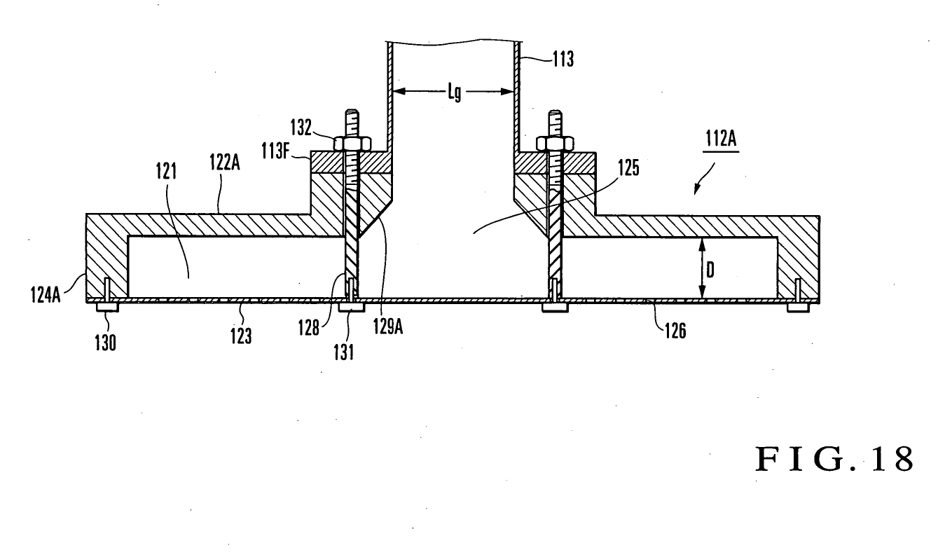

FIG. 18 is a sectional view showing the arrangement of the main body of the fourth embodiment of the present invention. In FIG. 18, the same or identical portions as in FIGS. 11 and 13 are denoted by the same reference numerals, and a description thereof will accordingly be omitted.

The electromagnetic field supply apparatus 110 shown in FIGS. 11 and 13 has the bump 127 and taper portion 129. The electromagnetic field supply apparatus shown in FIG. 18 has no bump 127. With only a taper portion 129A, however, the operation of moderating the impedance change from a cylindrical waveguide 113 to a radial waveguide 121 can be obtained. Thus, when the ratio of a diameter Lg of the cylindrical waveguide 113 to a height D of the radial waveguide 121 is adjusted, almost the same reflectance as that of the electromagnetic field supply apparatus 110 shown in FIGS. 11 and 13 can be obtained.

When the bump 127 is eliminated from a conductive plate 123 as shown in FIG. 18, the load acting on the conductive plate 123 can be further decreased. When an impact is applied to a RLSA 112A, the frequency with which support columns 128 that support the conductive plate 123 are damaged can be further decreased.

Fifth Embodiment

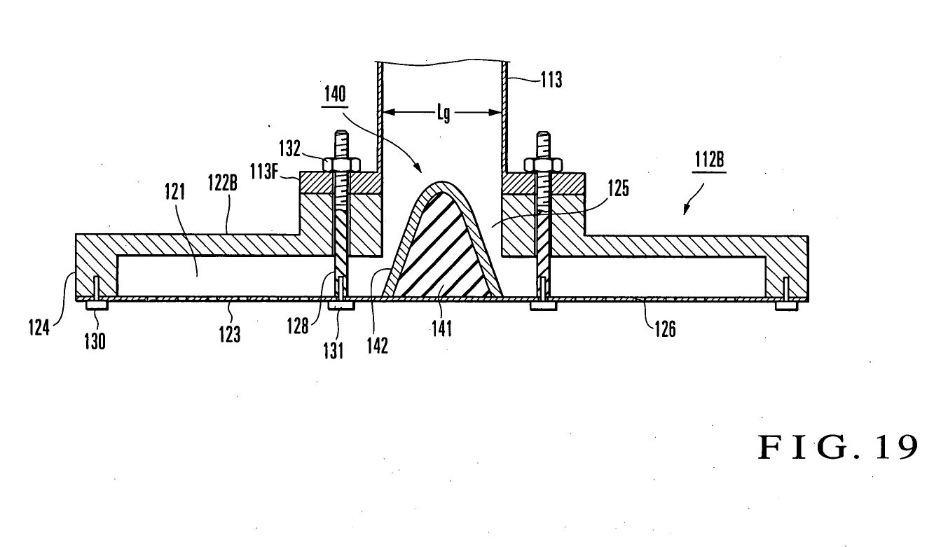

FIG. 19 is a sectional view showing the arrangement of the main part of the fifth embodiment of the present invention. In FIG. 19, the same or identical portions as in FIGS. 11 and 13 are denoted by the same reference numerals, and a description thereof will accordingly be omitted.

The electromagnetic field supply apparatus shown in FIG. 19 has a bump 140 including a bump main body 141 and a thin metal film 142 which covers the surface of the bump main body 141.

The bump main body 141 is made of a dielectric having a lower density than that of aluminum conventionally used for bump formation. More specifically, the bump main body 141 is made of a plastic material or the like having a density lower than 2.69×10³ kg/cm³ at 20° C. Alternatively, the bump main body 141 may be made of a porous material or the like having a density lower than that of aluminum. The size of the bump main body 141 may be almost the same as that of the conventionally used metal bump 327.

The thin metal film 142 is made of aluminum, copper, silver, or the like, and its thickness can be set to, e.g., about 0.1 mm. The thin metal film 142 need not cover the bump 140 down to its lower surface, i.e., to that surface of the bump 140 which opposes a conductive plate 123.

When the bump main body 141 is made of a material having a low density in this manner, the mass of the whole bump 140 can be decreased, so that the load acting on the conductive plate 123 can be decreased. When an impact is applied to a RLSA 112B, the frequency with which support columns 128 that support the conductive plate 123 are damaged can be decreased.

When the surface of the bump main body 141 is covered with the thin metal film 142, the same characteristics as those obtained when the whole bump is formed of a metal can be obtained.

In the electromagnetic field supply apparatus shown in FIG. 19, the frequency with which the support columns 128 are damaged can be decreased without making the support columns 128 thicker. Thus, the influence on the electromagnetic field in a radial waveguide 121 is small.

While no taper portion is formed at the connecting portion of a cylindrical waveguide 113 and the radial waveguide 121 in the electromagnetic field supply apparatus shown in FIG. 19, a taper portion 129 can be formed in the same manner as in FIG. 13. Then, the volume of the bump 140 is decreased, and accordingly the mass of the bump 140 can be further decreased. As a result, the load acting on the conductive plate 123 can be further decreased, and the frequency with which the support columns 128 are damaged can be further decreased.

Even if the bump is formed of a hollow metal member, the effect of decreasing the mass of the bump, the load acting on the conductive plate 123, and accordingly the frequency with which the support columns 128 that support the conductive plate 123 are damaged can be obtained.

In the above description, the microwave MW having a frequency of 2.45 GHz is used. The frequency that can be used is not limited to 2.45 GHz. The same effect can be obtained with, e.g., a microwave having a frequency of 1 GHz to ten-odd GHz. Furthermore, the same effect can also be obtained when a high frequency including a frequency band lower than the microwave is used.

The transmission mode of the cylindrical waveguide 113 can be TM₀₁ mode.

Although the slot antenna was exemplified by the RLSAs 112, 112A, and 112B, the slot antenna is not limited to them, but another slot antenna can be used.

Industrial Applicability

A plasma processing apparatus according to the present invention can be utilized in an etching apparatus, CVD apparatus, ashing apparatus, and the like.

1. An electromagnetic field supply apparatus characterized by comprising
a waveguide including a first conductive plate having a plurality of slots and a second conductive plate arranged opposite to said first conductive plate,
a cylindrical waveguide connected to an opening of said second conductive plate, and
a bump provided on said first conductive plate and projecting toward the opening of said second conductive plate, at least part of said bump being made of a dielectric.

2. An electromagnetic field supply apparatus according to claim 1, characterized in that a remaining part of said bump is made of a metal.

3. An electromagnetic field supply apparatus according to claim 1, characterized in that a distal end of said bump which is directed to the opening is rounded.

4. An electromagnetic field supply apparatus according to claim 1, characterized in that a connecting portion of said cylindrical waveguide and waveguide has a taper portion spreading from said cylindrical waveguide toward said waveguide.

5. An electromagnetic field supply apparatus according to claim 1, characterized by comprising support columns disposed around the opening of said second conductive plate, fastened to said first and second conductive plates, and made of a dielectric.

6. An electromagnetic field supply apparatus characterized by comprising
a waveguide consisting of a first conductive plate having a plurality of slots and a second conductive plate arranged opposite to said first conductive plate, and
a cylindrical waveguide connected to an opening of said second conductive plate,
wherein a connecting portion of said cylindrical waveguide and waveguide has a taper portion spreading from said cylindrical waveguide toward said waveguide.

7. An electromagnetic field supply apparatus according to claim 6, characterized by comprising a bump provided on said first conductive plate and projecting toward the opening of said second conductive plate.

8. An electromagnetic field supply apparatus according to claim 7, characterized in that said bump is made of a metal.

9. An electromagnetic field supply apparatus according to claim 7, characterized in that a distal end of said bump which is directed to the opening is rounded.

10. An electromagnetic field supply apparatus according to claim 6, characterized by comprising support columns disposed around the opening of said second conductive plate, fastened to said first and second conductive plates, and made of a dielectric.

11. An electromagnetic field supply apparatus characterized by comprising
a waveguide consisting of a first conductive plate having a plurality of slots and a second conductive plate arranged opposite to said first conductive plate,
a cylindrical waveguide connected to an opening of said second conductive plate, and
a bump provided on said first conductive plate and projecting toward the opening of said second conductive plate,
wherein said bump includes a bump main body made of a dielectric and a metal film covering a surface of said bump main body.

12. An electromagnetic field supply apparatus according to claim 11, characterized in that a connecting portion of said cylindrical waveguide and waveguide has a taper portion spreading from said cylindrical waveguide toward said waveguide.

13. An electromagnetic field supply apparatus according to claim 11, characterized in that a distal end of said bump which is directed to the opening is rounded.

14. An electromagnetic field supply apparatus according to claim 11, characterized by comprising support columns disposed around the opening of said second conductive plate, fastened to said first and second conductive plates, and made of a dielectric.

15. A plasma processing apparatus characterized by comprising
a processing vessel which accommodates a target object, and
an electromagnetic field supply apparatus which supplies an electromagnetic field into said processing vessel,
wherein said electromagnetic field supply apparatus comprises
a waveguide including a first conductive plate having a plurality of slots and a second conductive plate arranged opposite to said first conductive plate,
a cylindrical waveguide connected to an opening of said second conductive plate, and
a bump provided on said first conductive plate and projecting toward the opening of said second conductive plate, at least part of said bump being made of a dielectric.

16. A plasma processing apparatus according to claim 15, characterized in that a remaining part of said bump is made of a metal.

17. A plasma processing apparatus according to claim 15, characterized in that a distal end of said bump which is directed to the opening is rounded.

18. A plasma processing apparatus according to claim 15, characterized in that a connecting portion of said cylindrical waveguide and waveguide has a taper portion spreading from said cylindrical waveguide toward said waveguide.

19. A plasma processing apparatus according to claim 15, characterized by comprising support columns disposed around the opening of said second conductive plate, fastened to said first and second conductive plates, and made of a dielectric.

20. A plasma processing apparatus characterized by comprising
a processing vessel which accommodates a target object, and
an electromagnetic field supply apparatus which supplies an electromagnetic field into said processing vessel,
wherein said electromagnetic field supply apparatus comprises
a waveguide including a first conductive plate having a plurality of slots and a second conductive plate arranged opposite to said first conductive plate, and
a cylindrical waveguide connected to an opening of said second conductive plate,
a connecting portion of said cylindrical waveguide and waveguide having a taper portion spreading from said cylindrical waveguide toward said waveguide.

21. A plasma processing apparatus according to claim 20, characterized by comprising a bump provided on said first conductive plate and projecting toward the opening of said second conductive plate.

22. A plasma processing apparatus according to claim 21, characterized in that said bump is made of a metal.

23. A plasma processing apparatus according to claim 21, characterized in that a distal end of said bump which is directed to the opening is rounded.

24. A plasma processing apparatus according to claim 20, characterized by comprising support columns disposed around the opening of said second conductive plate, fastened to said first and second conductive plates, and made of a dielectric.

25. A plasma processing apparatus characterized by comprising
a processing vessel which accommodates a target object, and
an electromagnetic field supply apparatus which supplies an electromagnetic field into said processing vessel,
wherein said electromagnetic field supply apparatus comprises
a waveguide including a first conductive plate having a plurality of slots and a second conductive plate arranged opposite to said first conductive plate,
a cylindrical waveguide connected to an opening of said second conductive plate, and
a bump provided on said first conductive plate and projecting toward the opening of said second conductive plate,
said bump including a bump main body made of a dielectric and a metal film covering a surface of said bump main body.

26. A plasma processing apparatus according to claim 25, characterized in that a connecting portion of said cylindrical waveguide and waveguide has a taper portion spreading from said cylindrical waveguide toward said waveguide.

27. A plasma processing apparatus according to claim 25, characterized in that a distal end of said bump which is directed to the opening is rounded.

28. A plasma processing apparatus according to claim 25, characterized by comprising support columns disposed around the opening of said second conductive plate, fastened to said first and second conductive plates, and made of a dielectric.
